(19) United States
(12) Patent Application Publication
(10) Pub. No.: US 2019/0157616 A1
(43) Pub. Date: May 23, 2019

(54) OLED PACKAGE METHOD AND OLED PACKAGE STRUCTURE

(71) Applicant: Wuhan China Star Optoelectronics Technology Co., Ltd., Wuhan City (CN)

(72) Inventors: Simin Peng, Wuhan City (CN); Jiangjiang Jin, Wuhan City (CN)

(21) Appl. No.: 15/505,101

(22) PCT Filed: Dec. 28, 2016
(86) PCT No.: PCT/CN2016/112537

§ 371 Date: Feb. 20, 2017

(30) Foreign Application Priority Data
Dec. 19, 2016 (CN) 201611179979.9

(51) Int. Cl. H01L 51/52; H01L 51/56; C23C 16/26

(52) U.S. Cl. CPC H01L 51/5256; H01L 51/56; H01L 2251/5338; H01L 2251/10; C23C 16/26

(57) ABSTRACT

The present invention provides an OLED package method and an OLED package structure. By introducing the Ti-doped diamond-like carbon film layer into the OLED thin film package layers and utilizing the higher transmission rate, the better flexibility, the high heat conductivity and lower water and oxygen permeation rate of the Ti-doped diamond-like carbon film layer, it can promote the transmission rate, the bendable property, the high heat conductivity and the water and oxygen resistant property of the OLED thin film package layers, and thus to promote the usage performance and usage lifetime of the flexible OLED display panel.

### FIELD OF THE INVENTION

The present invention relates to a display technology field, and more particularly to an OLED package method and an OLED package structure.

### BACKGROUND OF THE INVENTION

The Organic Light Emitting Display (OLED) device possesses many outstanding properties of self-illumination, low driving voltage, high luminescence efficiency, short response time, high clarity and contrast, near 180° view angle, wide range of working temperature, applicability of flexible display and large scale full color display. The OLED is considered as the most potential display device.

The OLED can be categorized into two major types according to the driving ways, which are the Passive Matrix OLED (PMOLED) and the Active Matrix OLED (AMOLED), i.e. two types of the direct addressing and the Thin Film Transistor matrix addressing. The AMOLED comprises pixels arranged in array and belongs to active display type, which has high lighting efficiency and is generally utilized for the large scale display devices of high resolution.

The OLED display element generally comprises a substrate, an anode located on the substrate, a Hole Injection Layer located on the anode, a Hole Transporting Layer located on the Hole Injection Layer, an emitting layer located on the Hole Transporting Layer, an Electron Transport Layer located on the emitting layer, an Electron Injection Layer located on the Electron Transport Layer and a Cathode located on the Electron Injection Layer. The principle of the OLED element is that the illumination generates due to the carrier injection and recombination under the electric field driving of the semiconductor material and the organic semiconductor illuminating material. Specifically, the Indium Tin Oxide (ITO) electrode and the metal electrode are respectively employed as the anode and the cathode of the Display. Under certain voltage driving, the Electron and the Hole are respectively injected into the Electron and Hole Transporting Layers from the cathode and the anode. The Electron and the Hole respectively migrate from the Electron and Hole Transporting Layers to the Emitting layer and bump into each other in the Emitting layer to form an exciton to excite the emitting molecule. The latter can illuminate after the radiative relaxation.

Most of the package material of the OLED element uses the material of high density and good thermal conductivity to ensure that the organic layer and the electrode layer materials are totally insulated from the external environment, and the heat generated due to the long period working time of the OLED element is effectively guided out. Diamond-Like Carbon (DLC) possesses the good abrasion resistance, the better corrosion resistance, high density and high thermal conductivity, and meanwhile, has the low water penetration rate for moisture. Therefore, for the general organic material or ceramic material, it has a certain advantage in the package process of the OLED.

At present, the OLED package structure applied with the DLC material generally utilizes the structure of DLC film/buffer layer/DLC film/buffer layer alternation, such as the package structure utilizing DLC film and buffer layer alternation disclosed in patent US20040056269 of Kuang-Jung Chen. The DLC film is used to block water and oxygen outside, and the buffer layer is used to relieve the stress. Then, in patents CN1328936C, US20060078677, a series of package process of such type can be seen. However, the density of the pure DLC film is higher, and thus, the transmission rate is not high and the stress of the film is very large, and the fracture can easily appears as being bent.

Xiaowei Li et al reported the influence to the stress of the DLC film after utilizing titanium (Ti) of different concentration doping the DLC in Elsevier. The result indicates that along with the increase of the Ti content, the film stress shows the trend of First decrease and then increase. The research provides an excellent guide solution for solving the issue that the fracture can easily appear as the DLC film is bent.

### SUMMARY OF THE INVENTION

An objective of the present invention is to provide an OLED package method, which can promote the transmission rate, the bendable property, the high heat conductivity and the water and oxygen resistant property of the OLED thin film package layers, and thus to promote the usage performance and usage lifetime of the flexible OLED display panel.

Another objective of the present invention is to provide an OLED package structure, which can promote the transmission rate, the bendable property, the high heat conductivity and the water and oxygen resistant property of the OLED thin film package layers, and thus to promote the usage performance and usage lifetime of the flexible OLED display panel.

For realizing the aforesaid objective, the present invention first provides the first embodiment of the OLED package method, comprising steps of:

step 1, providing an OLED element, and forming a first inorganic layer on the OLED element, and the first inorganic layer covering the OLED element with an entire surface;

step 2, forming a first Ti-doped diamond-like carbon film layer on the first inorganic layer, and the first Ti-doped diamond-like carbon film layer covering the first inorganic layer with an entire surface;

step 3, forming a first organic layer on the first Ti-doped diamond-like carbon film layer, and the first organic layer covering the first Ti-doped diamond-like carbon film layer with an entire surface;

step 4, forming a second inorganic layer on the first organic layer, and the second inorganic layer covering the first organic layer with an entire surface.

The present invention further provides the second embodiment of the OLED package method, and the difference from the first embodiment of the OLED package method is that the method further comprises:

step 5, forming a second Ti-doped diamond-like carbon film layer on the second inorganic layer, and the second Ti-doped diamond-like carbon film layer covering the second inorganic layer with an entire surface.

The present invention further provides the third embodiment of the OLED package method, and the difference from the first embodiment of the OLED package method is that the method further comprises:

step 5′, forming a second organic layer on the second inorganic layer, and the second organic layer covering the second inorganic layer with an entire surface;

forming a third inorganic layer on the second organic layer, and the third inorganic layer covering the second organic layer with an entire surface.

The present invention further provides the fourth embodiment of the OLED package method, and the difference from the first embodiment of the OLED package method is that the method further comprises:

step 6, forming a second organic layer on the second Ti-doped diamond-like carbon film layer, and the second organic layer covering the second Ti-doped diamond-like carbon film layer with an entire surface;

forming a third inorganic layer on the second organic layer, and the third inorganic layer covering the second organic layer with an entire surface.

The present invention further provides the fifth embodiment of the OLED package method, and the difference from the fourth embodiment of the OLED package method is that the method further comprises:

step 7, forming a third Ti-doped diamond-like carbon film layer on the third inorganic layer, and the third Ti-doped diamond-like carbon film layer covering the third inorganic layer with an entire surface.

The present invention further provides the first embodiment of an OLED package structure, comprising an OLED element, a first inorganic layer being located on the OLED element and covering the OLED element with an entire surface, a first Ti-doped diamond-like carbon film layer being located on the first inorganic layer and covering the first inorganic layer with an entire surface, a first organic layer being located on the first Ti-doped diamond-like carbon film layer and covering the first Ti-doped diamond-like carbon film layer with an entire surface and a second inorganic layer being located on the first organic layer and covering the first organic layer with an entire surface.

The present invention further provides the second embodiment of the OLED package structure, and the difference from the aforesaid first embodiment of the OLED package structure is that the structure further comprises: a second Ti-doped diamond-like carbon film layer being located on the second inorganic layer, and covering the second inorganic layer with an entire surface.

The present invention further provides the third embodiment of the OLED package structure, and the difference from the aforesaid first embodiment of the OLED package structure is that the structure further comprises: a second organic layer being located on the second inorganic layer, and covering the second inorganic layer with an entire surface, and a third inorganic layer being located on the second organic layer, and covering the second organic layer with an entire surface.

The present invention further provides the fourth embodiment of the OLED package structure, and the difference from the aforesaid second embodiment of the OLED package structure is that the structure further comprises: the OLED package structure further comprising: a second organic layer being located on the second Ti-doped diamond-like carbon film layer, and covering the second Ti-doped diamond-like carbon film layer with an entire surface, and a third inorganic layer being located on the second organic layer, and covering the second organic layer with an entire surface.

The present invention further provides the fifth embodiment of the OLED package structure, and the difference from the aforesaid fourth embodiment of the OLED package structure is that the structure further comprises: a third Ti-doped diamond-like carbon film layer being located on the third inorganic layer, and covering the third inorganic layer with an entire surface.

The present invention further provides an OLED package structure, comprising an OLED element, a first inorganic layer being located on the OLED element and covering the OLED element with an entire surface, a first Ti-doped diamond-like carbon film layer being located on the first inorganic layer and covering the first inorganic layer with an entire surface, a first organic layer being located on the first Ti-doped diamond-like carbon film layer and covering the first Ti-doped diamond-like carbon film layer with an entire surface and a second inorganic layer being located on the first organic layer and covering the first organic layer with an entire surface;

the OLED package structure further comprising: a second Ti-doped diamond-like carbon film layer being located on the second inorganic layer, and covering the second inorganic layer with an entire surface;

the OLED package structure further comprising: a second organic layer being located on the second Ti-doped diamond-like carbon film layer, and covering the second Ti-doped diamond-like carbon film layer with an entire surface, and a third inorganic layer being located on the second organic layer, and covering the second organic layer with an entire surface.

The benefits of the present invention are: the present invention provides an OLED package method and an OLED package structure. By introducing the Ti-doped diamond-like carbon film layer into the OLED thin film package layers and utilizing the higher transmission rate, the better flexibility, the high heat conductivity and lower water and oxygen permeation rate of the Ti-doped diamond-like carbon film layer, it can promote the transmission rate, the bendable property, the high heat conductivity and the water and oxygen resistant property of the OLED thin film package layers, and thus to promote the usage performance and usage lifetime of the flexible OLED display panel.

In order to better understand the characteristics and technical aspect of the invention, please refer to the following detailed description of the present invention is concerned with the diagrams, however, provide reference to the accompanying drawings and description only and is not intended to be limiting of the invention.

### BRIEF DESCRIPTION OF THE DRAWINGS

The technical solution and the beneficial effects of the present invention are best understood from the following detailed description with reference to the accompanying figures and embodiments.

In drawings,

FIG. 1 is a flowchart of the first embodiment according to the OLED package method of the present invention;

FIGS. 2-3 are diagrams of step 1 of the first embodiment according to the OLED package method of the present invention;

FIG. 4 is a diagram of step 2 of the first embodiment according to the OLED package method of the present invention;

FIG. 5 is a diagram of step 3 of the first embodiment according to the OLED package method of the present invention;

FIG. 6 is a diagram of step 4 of the first embodiment according to the OLED package method of the present invention and also a sectional diagram of the first embodiment according to the OLED package structure of the present invention;

FIG. 7 is a diagram of step 5 of the second embodiment according to the OLED package method of the present invention and also a sectional diagram of the second embodiment according to the OLED package structure of the present invention;

FIG. 8 is a diagram of step 5′ of the third embodiment according to the OLED package method of the present invention and also a sectional diagram of the third embodiment according to the OLED package structure of the present invention;

FIG. 9 is a diagram of step 6 of the fourth embodiment according to the OLED package method of the present invention and also a sectional diagram of the fourth embodiment according to the OLED package structure of the present invention;

FIG. 10 is a diagram of step 7 of the fifth embodiment according to the OLED package method of the present invention and also a sectional diagram of the fifth embodiment according to the OLED package structure of the present invention.

### DETAILED DESCRIPTION OF PREFERRED EMBODIMENTS

For better explaining the technical solution and the effect of the present invention, the present invention will be further described in detail with the accompanying drawings and the specific embodiments.

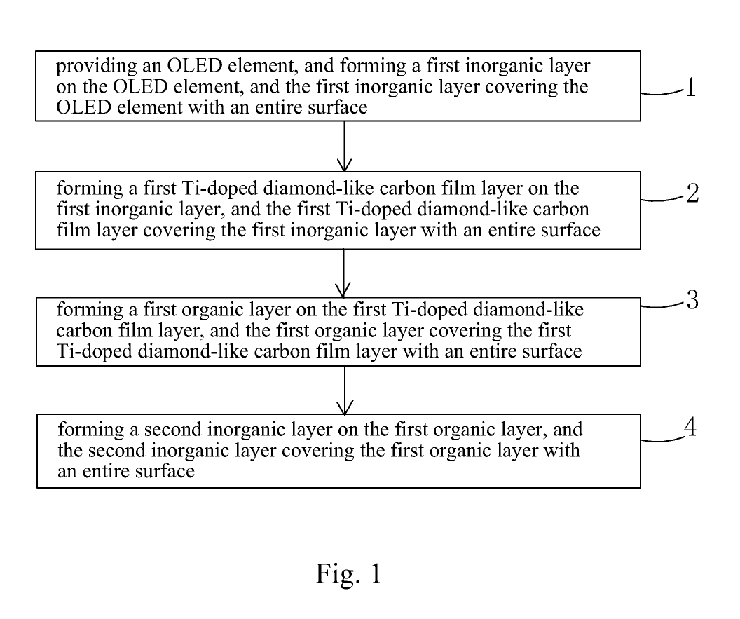

Please refer to FIG. 1, which is the first embodiment according to the OLED package method of the present invention, which comprises steps of:

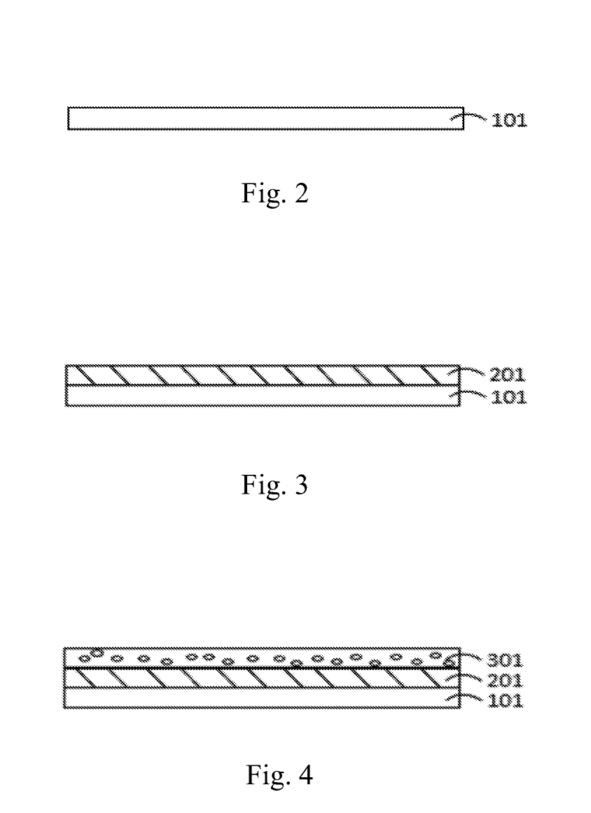

step 1, as shown in FIG. 2 and FIG. 3, providing an OLED element 101, and forming a first inorganic layer 201 on the OLED element 101, and the first inorganic layer 201 covering the OLED element 101 with an entire surface.

Specifically, in step 1, Plasma Enhanced Chemical Vapor Deposition (PECVD), Atomic Layer Deposition (ALD), Pulsed Laser Deposition (PLD) or Sputter is utilized to form the first inorganic layer 201.

Specifically, a material of the first inorganic layer 201 comprises one or more of aluminum oxide (Al₂O₃), titanium oxide (TiO₂), silicon nitride (SiNₓ), silicon carbon nitride (SiCNₓ) and silicon oxide (SiOₓ).

Specifically, a thickness of the first inorganic layer 201 is 0.5 μm-1 μm.

Specifically, the function of the first inorganic layer 201 is to stop the corrosion of the external water and oxygen to the OLED element 101.

step 2, as shown in FIG. 4, forming a first Ti-doped diamond-like carbon film (Ti doped in DLC film) layer 301 on the first inorganic layer 201, and the first Ti-doped diamond-like carbon film layer 301 covering the first inorganic layer 201 with an entire surface.

Specifically, in step 2, Plasma Enhanced Chemical Vapor Deposition (PECVD), High Density Plasma CVD (HDPCVD) or Inductively Coupled Plasma Chemical Vapor Deposition (ICPCVD) is utilized to form the first Ti-doped diamond-like carbon film layer 301.

Specifically, a material of the first Ti-doped diamond-like carbon film layer 301 is diamond-like carbon doped with titanium, wherein the content of the titanium is 1 wt %˜10 wt %.

Specifically, a thickness of the first Ti-doped diamond-like carbon film layer 301 is 1 nm-1000 nm.

By doping the titanium in the diamond-like carbon, the density of the diamond-like carbon can be decreased, and thus to raise the transmission rate of the diamond-like carbon film, and meanwhile to reduce the stress of the diamond-like carbon film; thus, the present invention locates the first Ti-doped diamond-like carbon film layer 301 into the OLED thin film package layers and utilizes the higher transmission rate, the better flexibility, the high heat conductivity and lower water and oxygen permeation rate of the first Ti-doped diamond-like carbon film layer 301 to promote the transmission rate, the bendable property, the high heat conductivity and the water and oxygen resistant property of the OLED thin film package layers, and thus to promote the usage performance and usage lifetime of the flexible OLED display panel.

Specifically, by raising the transmission rate of the OLED thin film package layers, the light output efficiency of the OLED element 101 can be raised; by raising the heat conduction property of the OLED thin film package layers, it can effectively transmit the heat in the OLED element 101 to the exterior to promote the usage lifetime of the OLED element 101; by raising the water and oxygen resistant property of the OLED thin film package layers, it can protect the OLED element 101 from the corrosion of the external water and oxygen, and promote the usage lifetime of the OLED element 101 in advance; by raising the bendable property of the OLED thin film package layers, it can prevent the appearance of fracture as the OLED thin film package layers are bent to promote the usage lifetime of the OLED thin film package layers.

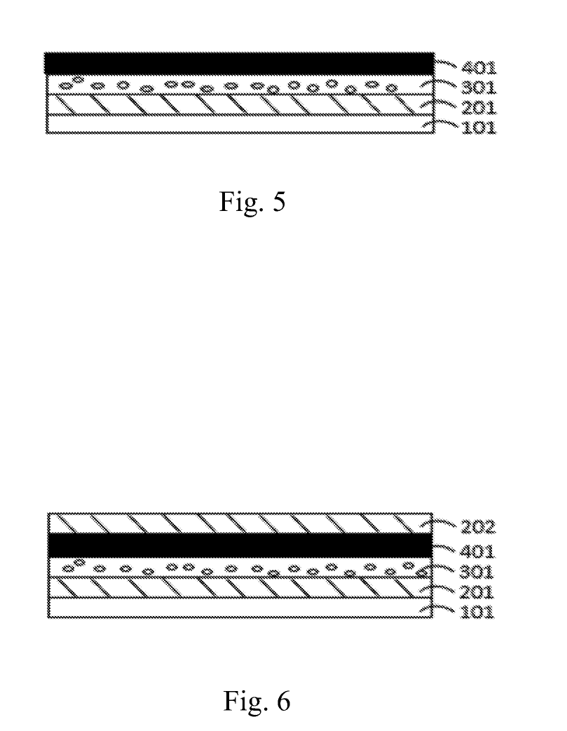

step 3, as shown in FIG. 5, forming a first organic layer 401 on the first Ti-doped diamond-like carbon film layer 301, and the first organic layer 401 covering the first Ti-doped diamond-like carbon film layer 301 with an entire surface.

Specifically, in step 3, Ink Jet Printing (IJP) or Plasma Enhanced Chemical Vapor Deposition (PECVD) is utilized to form the first organic layer 401.

Specifically, a material of the first organic layer 401 comprises one or more of acrylic, HMDSO, polyhydroxy acrylics, polycarbonate and polystyrene.

Specifically, a thickness of the first organic layer 401 is 4 μm -8 μm.

Specifically, the first organic layer 401 mainly acts to relieve the stress of the OLED display panel as being bent, folded and acts for planarization.

step 4, as shown in FIG. 6, forming a second inorganic layer 202 on the first organic layer 401, and the second inorganic layer 202 covering the first organic layer 401 with an entire surface.

Specifically, in step 4, the material, the thickness and the manufacture process of the second inorganic layer 202 are the same as these of the first inorganic layer 201.

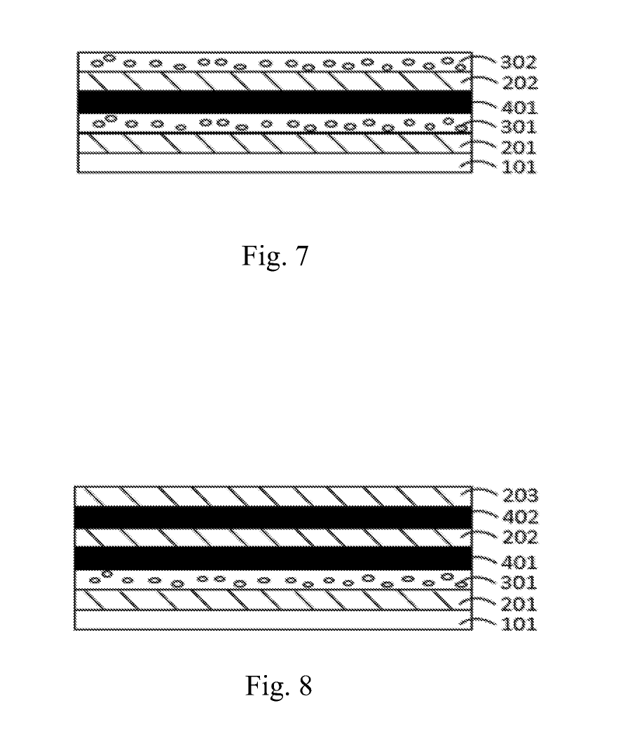

Please refer to FIG. 2 to FIG. 6 with FIG. 7, which is the second embodiment according to the OLED package method of the present invention, together. The step 1 to step 4 of the second embodiment of the OLED package method are the same as these of the first embodiment of the OLED package method. The difference is that the method further comprises:

step 5, as shown in FIG. 7, forming a second Ti-doped diamond-like carbon film layer 302 on the second inorganic layer 202, and the second Ti-doped diamond-like carbon film layer 302 covering the second inorganic layer 202 with an entire surface.

Specifically, in step 5, the material, the thickness and the manufacture process of the second Ti-doped diamond-like carbon film layer 302 are the same as these of the first Ti-doped diamond-like carbon film layer 301.

Please refer to FIG. 2 to FIG. 6 with FIG. 8, which is the third embodiment according to the OLED package method of the present invention, together. The step 1 to step 4 of the third embodiment of the OLED package method are the same as these of the first embodiment of the OLED package method. The difference is that the method further comprises:

step 5′, as shown in FIG. 8, forming a second organic layer 402 on the second inorganic layer 202, and the second organic layer 402 covering the second inorganic layer 202 with an entire surface;

forming a third inorganic layer 203 on the second organic layer 402, and the third inorganic layer 203 covering the second organic layer 402 with an entire surface.

Specifically, in step 5′, the material, the thickness and the manufacture process of the second organic layer 402 are the same as these of the first organic layer 401; the material, the thickness and the manufacture process of the third inorganic layer 203 are the same as these of the first inorganic layer 201 and the second inorganic layer 202.

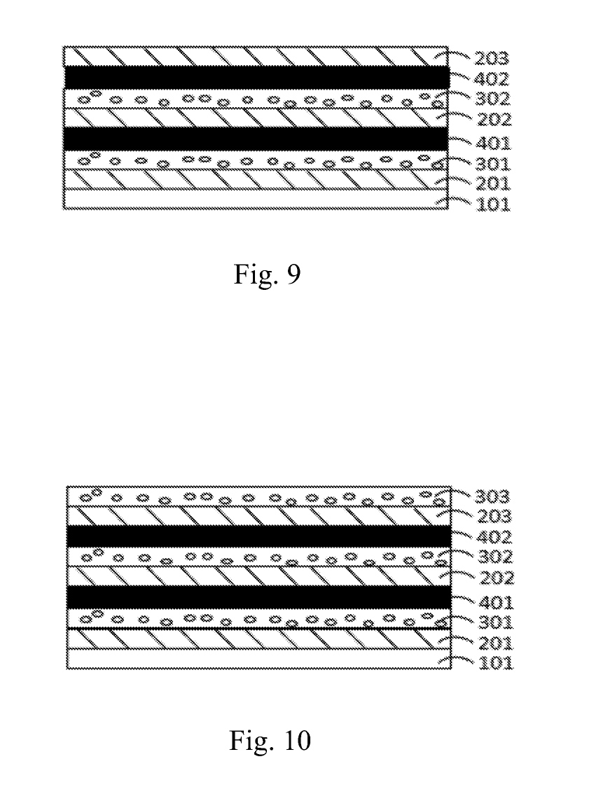

Please refer to FIG. 2 to FIG. 7 with FIG. 9, which is the fourth embodiment according to the OLED package method of the present invention, together. The step 1 to step 5 of the fourth embodiment of the OLED package method are the same as these of the second embodiment of the OLED package method. The difference is that the method further comprises:

step 6, as shown in FIG. 9, forming a second organic layer 402 on the second Ti-doped diamond-like carbon film layer 302, and the second organic layer 402 covering the second Ti-doped diamond-like carbon film layer 302 with an entire surface;

forming a third inorganic layer 203 on the second organic layer 402, and the third inorganic layer 203 covering the second organic layer 402 with an entire surface.

Specifically, in step 6, the material, the thickness and the manufacture process of the second organic layer 402 are the same as these of the first organic layer 401; the material, the thickness and the manufacture process of the third inorganic layer 203 are the same as these of the first inorganic layer 201 and the second inorganic layer 202.

Please refer to FIG. 2 to FIG. 7, FIG. 9 with FIG. 10 which is the fifth embodiment according to the OLED package method of the present invention, together. The step 1 to step 6 of the fifth embodiment of the OLED package method are the same as these of the fourth embodiment of the OLED package method. The difference is that the method further comprises:

step 7, as shown in FIG. 10, forming a third Ti-doped diamond-like carbon film layer 303 on the third inorganic layer 203, and the third Ti-doped diamond-like carbon film layer 303 covering the third inorganic layer 203 with an entire surface.

Specifically, in step 7, the material, the thickness and the manufacture process of the third Ti-doped diamond-like carbon film layer 303 are the same as these of the first Ti-doped diamond-like carbon film layer 301 and the second Ti-doped diamond-like carbon film layer 302.

In the aforesaid OLED package method, by introducing the Ti-doped diamond-like carbon film layer into the OLED thin film package layers and utilizing the higher transmission rate, the better flexibility, the high heat conductivity and lower water and oxygen permeation rate of the Ti-doped diamond-like carbon film layer, it can promote the transmission rate, the bendable property, the high heat conductivity and the water and oxygen resistant property of the OLED thin film package layers, and thus to promote the usage performance and usage lifetime of the flexible OLED display panel.

On the basis of the aforesaid OLED package method, the present invention further provides an OLED package structure. Please refer to FIG. 6, which is the first embodiment of the OLED package structure according to the present invention, comprising an OLED element 101, a first inorganic layer 201 being located on the OLED element 101 and covering the OLED element 101 with an entire surface, a first Ti-doped diamond-like carbon film layer 301 being located on the first inorganic layer 201 and covering the first inorganic layer 201 with an entire surface, a first organic layer 401 being located on the first Ti-doped diamond-like carbon film layer 301 and covering the first Ti-doped diamond-like carbon film layer 301 with an entire surface and a second inorganic layer 202 being located on the first organic layer 401 and covering the first organic layer 401 with an entire surface.

Specifically, a material of the first inorganic layer 201 comprises one or more of aluminum oxide (Al₂O₃), titanium oxide (TiO₂), silicon nitride (SiNₓ), silicon carbon nitride (SiCNₓ) and silicon oxide (SiOₓ).

Specifically, a thickness of the first inorganic layer 201 is 0.5 μm-1 μm.

Specifically, a material of the first Ti-doped diamond-like carbon film layer 301 is diamond-like carbon doped with titanium, wherein the content of the titanium is 1 wt %˜10 wt %.

Specifically, a thickness of the first Ti-doped diamond-like carbon film layer 301 is 1 nm-1000 nm.

Specifically, a material of the first organic layer 401 comprises one or more of acrylic, HMDSO, polyhydroxy acrylics, polycarbonate and polystyrene.

Specifically, a thickness of the first organic layer 401 is 4 μm -8 μm.

Specifically, the material and the thickness of the second inorganic layer 202 are the same as these of the first inorganic layer 201.

Please refer to FIG. 7, which is the second embodiment of the OLED package structure of the present invention. The difference of the second embodiment of the OLED package structure from the first embodiment of the OLED package structure is that the structure further comprises: a second Ti-doped diamond-like carbon film layer 302 being located on the second inorganic layer 202, and covering the second inorganic layer 202 with an entire surface.

Specifically, the material and the thickness of the second Ti-doped diamond-like carbon film layer 302 are the same as these of the first Ti-doped diamond-like carbon film layer 301.

Please refer to FIG. 8, which is the third embodiment of the OLED package structure of the present invention. The difference of the third embodiment of the OLED package structure from the first embodiment of the OLED package structure is that the structure further comprises: a second organic layer 402 being located on the second inorganic layer 202, and covering the second inorganic layer 202 with an entire surface, and a third inorganic layer 203 being located on the second organic layer 402, and covering the second organic layer 402 with an entire surface.

Specifically, the material and the thickness of the second organic layer 402 are the same as these of the first organic layer 401; the material and the thickness of the third inorganic layer 203 are the same as these of the first inorganic layer 201 and the second inorganic layer 202.

Please refer to FIG. 9, which is the fourth embodiment of the OLED package structure of the present invention. The difference of the fourth embodiment of the OLED package structure from the second embodiment of the OLED package structure is that the structure further comprises:

a second organic layer 402 being located on the second Ti-doped diamond-like carbon film layer 302, and covering the second Ti-doped diamond-like carbon film layer 302 with an entire surface, and a third inorganic layer 203 being located on the second organic layer 402, and covering the second organic layer 402 with an entire surface.

Specifically, the material and the thickness of the second organic layer 402 are the same as these of the first organic layer 401; the material and the thickness of the third inorganic layer 203 are the same as these of the first inorganic layer 201 and the second inorganic layer 202.

Please refer to FIG. 10, which is the fifth embodiment of the OLED package structure of the present invention. The difference of the fifth embodiment of the OLED package structure from the fourth embodiment of the OLED package structure is that the structure further comprises: a third Ti-doped diamond-like carbon film layer 303 being located on the third inorganic layer 203, and covering the third inorganic layer 203 with an entire surface.

Specifically, the material and the thickness of the third Ti-doped diamond-like carbon film layer 303 are the same as these of the first Ti-doped diamond-like carbon film layer 301 and the second Ti-doped diamond-like carbon film layer 302.

In the aforesaid OLED package structure, by introducing the Ti-doped diamond-like carbon film layer into the OLED thin film package layers and utilizing the higher transmission rate, the better flexibility, the high heat conductivity and lower water and oxygen permeation rate of the Ti-doped diamond-like carbon film layer, it can promote the transmission rate, the bendable property, the high heat conductivity and the water and oxygen resistant property of the OLED thin film package layers, and thus to promote the usage performance and usage lifetime of the flexible OLED display panel.

In conclusion, in the OLED package method and an OLED package structure of the present invention, by introducing the Ti-doped diamond-like carbon film layer into the OLED thin film package layers and utilizing the higher transmission rate, the better flexibility, the high heat conductivity and lower water and oxygen permeation rate of the Ti-doped diamond-like carbon film layer, it can promote the transmission rate, the bendable property, the high heat conductivity and the water and oxygen resistant property of the OLED thin film package layers, and thus to promote the usage performance and usage lifetime of the flexible OLED display panel.

Above are only specific embodiments of the present invention, the scope of the present invention is not limited to this, and to any persons who are skilled in the art, change or replacement which is easily derived should be covered by the protected scope of the invention. Thus, the protected scope of the invention should go by the subject claims.

What is claimed is:

1. An OLED package method, comprising steps of:
step 1, providing an OLED element, and forming a first inorganic layer on the OLED element, and the first inorganic layer covering the OLED element with an entire surface;
step 2, forming a first Ti-doped diamond-like carbon film layer on the first inorganic layer, and the first Ti-doped diamond-like carbon film layer covering the first inorganic layer with an entire surface;
step 3, forming a first organic layer on the first Ti-doped diamond-like carbon film layer, and the first organic layer covering the first Ti-doped diamond-like carbon film layer with an entire surface;
step 4, forming a second inorganic layer on the first organic layer, and the second inorganic layer covering the first organic layer with an entire surface.

2. The OLED package method according to claim 1, further comprising:
step 5, forming a second Ti-doped diamond-like carbon film layer on the second inorganic layer, and the second Ti-doped diamond-like carbon film layer covering the second inorganic layer with an entire surface.

3. The OLED package method according to claim 1, further comprising:
step 5′, forming a second organic layer on the second inorganic layer, and the second organic layer covering the second inorganic layer with an entire surface;
forming a third inorganic layer on the second organic layer, and the third inorganic layer covering the second organic layer with an entire surface.

4. The OLED package method according to claim 2, further comprising:
step 6, forming a second organic layer on the second Ti-doped diamond-like carbon film layer, and the second organic layer covering the second Ti-doped diamond-like carbon film layer with an entire surface;
forming a third inorganic layer on the second organic layer, and the third inorganic layer covering the second organic layer with an entire surface.

5. The OLED package method according to claim 4, further comprising:
step 7, forming a third Ti-doped diamond-like carbon film layer on the third inorganic layer, and the third Ti-doped diamond-like carbon film layer covering the third inorganic layer with an entire surface.

6. An OLED package structure, comprising an OLED element, a first inorganic layer being located on the OLED element and covering the OLED element with an entire surface, a first Ti-doped diamond-like carbon film layer being located on the first inorganic layer and covering the first inorganic layer with an entire surface, a first organic layer being located on the first Ti-doped diamond-like carbon film layer and covering the first Ti-doped diamond-like carbon film layer with an entire surface and a second inorganic layer being located on the first organic layer and covering the first organic layer with an entire surface.

7. The OLED package structure according to claim 6, further comprising: a second Ti-doped diamond-like carbon film layer being located on the second inorganic layer, and covering the second inorganic layer with an entire surface.

8. The OLED package structure according to claim 6, further comprising: a second organic layer being located on the second inorganic layer, and covering the second inorganic layer with an entire surface, and a third inorganic layer being located on the second organic layer, and covering the second organic layer with an entire surface.

9. The OLED package structure according to claim 7, further comprising: a second organic layer being located on the second Ti-doped diamond-like carbon film layer, and covering the second Ti-doped diamond-like carbon film layer with an entire surface, and a third inorganic layer being located on the second organic layer, and covering the second organic layer with an entire surface.

10. The OLED package structure according to claim 9, further comprising: a third Ti-doped diamond-like carbon film layer being located on the third inorganic layer, and covering the third inorganic layer with an entire surface.

11. An OLED package structure, comprising an OLED element, a first inorganic layer being located on the OLED element and covering the OLED element with an entire surface, a first Ti-doped diamond-like carbon film layer being located on the first inorganic layer and covering the first inorganic layer with an entire surface, a first organic layer being located on the first Ti-doped diamond-like carbon film layer and covering the first Ti-doped diamond-like carbon film layer with an entire surface and a second inorganic layer being located on the first organic layer and covering the first organic layer with an entire surface;
the OLED package structure further comprising: a second Ti-doped diamond-like carbon film layer being located on the second inorganic layer, and covering the second inorganic layer with an entire surface;
the OLED package structure further comprising: a second organic layer being located on the second Ti-doped diamond-like carbon film layer, and covering the second Ti-doped diamond-like carbon film layer with an entire surface, and a third inorganic layer being located on the second organic layer, and covering the second organic layer with an entire surface.

12. The OLED package structure according to claim 11, further comprising: a third Ti-doped diamond-like carbon film layer being located on the third inorganic layer, and covering the third inorganic layer with an entire surface.
